(19) United States
(12) Patent Application Publication
(10) Pub. No.: US 2004/0046248 A1
(43) Pub. Date: Mar. 11, 2004

(54) Microsystem packaging and associated methods

(75) Inventors: Marc Waelti, East Hampstead, NH (US); Amy Catherine Bowman, Westford, MA (US); William Patrick Taylor, North Andover, MA (US); Jin Zou, Woburn, MA (US)

Correspondence Address: HALE AND DORR, LLP, 60 STATE STREET, BOSTON, MA, 02109

(73) Assignee: Corning Intellisense Corporation

(21) Appl. No.: 10/235,363

(22) Filed: Sep. 5, 2002

(51) Int. Cl. H01L 23/34; H01L 23/48; H01L 23/52

(52) U.S. Cl. 257/712; 257/722; 257/713; 257/778

(57) ABSTRACT

Methods and apparatus are provided for sealing and reducing warpage in a microsystem device. The microsystem device is assembled with a substrate and packaged.

### BACKGROUND OF THE INVENTION

1. Field of the Invention

The present invention relates generally to microsystem devices and, more particularly, to methods and apparatus for packaging microsystem devices and maintaining the flatness of such devices, and to the integration of magnet assemblies into microsystem packages, and methods for hermetically sealing such packages.

2. Description of Related Art

Microsystem devices include, but are not limited to, optical microelectromechanical system (MOEMS) devices, microelectromechanical system (MEMS) devices, electro-optical devices, electromechanical devices, electrothermal devices, piezoelectric devices, electromagnetic devices, electrostatic devices, and any combination of such devices with one another or with electronic devices. These devices generally include a die or chip on which the functional components of the device are fabricated. For example, in a magnetic MEMS mirror device, the functional components can include selectively rotatable mirror structures fabricated on a chip. The microsystem devices are typically packaged and hermetically sealed to protect device components from the environment, e.g., from moisture, dust, and physical contact.

It is important to keep the device die very flat during both device packaging and service in the field. The die should maintain a given flatness specification over functional temperature ranges. Die bow or warping can occur from thermo-mechanical stresses in the device and packaging, and can damage the device, or adversely influence its performance. Thermo-mechanical stress in the devices are caused by thermal mismatch, such as coefficient of thermal expansion (CTE) mismatches between the die and packaging materials. CTE mismatches result in movement of materials relative to each other from temperature changes, resulting in stress in the materials.

Attempts have been made to maintain device flatness by reducing thermo-mechanical stress in the devices by using packaging and die materials having matching CTEs. However, conventional hermetic packaging using CTE matching materials has been found to be both expensive, and not particularly effective at reducing die warpage. This is largely due to the limited choice of materials available for conventional hermetic packaging. These available materials generally do not have very closely matching CTEs and/or are expensive.

Furthermore, for microsystem devices using magnets, it is generally difficult to include the magnets in conventional hermetically sealed packaging. Conventional hermetic packaging technology generally requires high temperature assembly and sealing processes that typically degenerate the strength of magnets or exceed their Curie temperature. Also, magnets often require active alignment of their magnetic fields with respect to active structures, which is difficult to achieve inside of a hermetically sealed package.

### BRIEF SUMMARY OF EMBODIMENTS OF THE INVENTION

In accordance with some embodiments of the invention, a microsystem package is provided including a microsystem device having a device die, and a substrate to which the microsystem device is flip chip bonded. The substrate has a CTE substantially matching that of the device die, and includes an opening for transmission of signals therethrough to the device.

In accordance with some embodiments of the invention, a microsystem package is provided including a microsystem device and a substrate having a recess for receiving the microsystem device. A material is provided between sides of the microsystem device and sidewalls defining the recess in the substrate for reducing thermo-mechanical stresses applied to the microsystem device.

In accordance with some embodiments of the invention, a microsystem device package is provided including a substrate having an opening extending therethrough, a microsystem device flip chip bonded to one side of the substrate around the opening, and a signal transfer window having a CTE substantially matching that of the device. The signal transfer window is positioned at the opening and allows signals to be transmitted therethrough to the device. The signal transfer window hermetically seals at least a portion of the microsystem device.

In accordance with some embodiments of the invention, a microsystem device package is provided including a substrate and a microsystem device wire bonded to the substrate. The microsystem device has a die with a CTE substantially matching that of the substrate. A signal transmission window allows transmission of signals therethrough to the device. The signal transmission window is mounted on and hermitically seals at least a portion of the device.

In accordance with some embodiments of the invention, a microsystem device package is provided including a microsystem device, and a substrate on which the microsystem device is mounted. The substrate includes at least one slot therein for increasing compliance of the substrate and reducing thermo-mechanical stresses applied to the device.

In accordance with some embodiments of the invention, a microsystem device package is provided including a microsystem device having a device die, and a substrate on which the microsystem device is mounted. An interposer structure is positioned between the device die and the substrate for substantially decoupling the die from thermo-mechanical stresses resulting from relative movement of the substrate.

In accordance with some embodiments of the invention, an electromagnetic device assembly is provided that includes a package substrate, at least one magnet mounted on the package substrate, an electromagnetic device including a device die, and at least one interposer plate, on which the electromagnetic device is flip chip bonded. The at least one interposer plate is connected to the substrate.

In accordance with some embodiments of the invention, a method is provided of manufacturing an electromagnetic device package. The method includes the steps of making a die-interposer subassembly by positioning two interposer plates along opposite sides of an electromagnetic device and flip chip bonding the device to the plates, assembling at least one magnet with a package substrate, assembling the die-interposer subassembly with the substrate such that the two interposer plates generally straddle the at least one magnet, and wire bonding the interposer plates to the substrate.

These and other features of the present invention will become readily apparent from the following detailed description wherein embodiments of the invention are shown and described by way of illustration of the best mode of the invention. As will be realized, the invention is capable of other and different embodiments and its several details may be capable of modifications in various respects, all without departing from the invention. Accordingly, the drawings and description are to be regarded as illustrative in nature and not in a restrictive or limiting sense with the scope of the application being indicated in the claims.

### BRIEF DESCRIPTION OF THE DRAWINGS

For a fuller understanding of the nature and objects of the present invention, reference should be made to the following detailed description taken in connection with the accompanying drawings wherein:

FIG. 1A is a schematic cross-sectional view of a microsystem package having a device flip chip attached to a package substrate in accordance with some embodiments of the invention;

FIG. 1B is a bottom view of the FIG. 1A package;

FIG. 2 is a is a schematic cross-sectional view of a package having a microsystem device wirebonded to a package substrate in accordance with some embodiments of the invention;

FIG. 3 is a schematic cross-sectional view of a package having a microsystem device flip chip attached to a package substrate in accordance with some embodiments of the invention;

FIG. 4 is a is a schematic cross-sectional view of a package having a microsystem device wirebonded to a package substrate in accordance with some embodiments of the invention;

FIG. 5 is a perspective view of a slotted package substrate in accordance with some embodiments of the invention;

FIG. 6 is a schematic side view of a package having a thermo-mechanically symmetrical structure in accordance with some embodiments of the invention;

FIG. 7 is a schematic side view of a package having a soft material stress decoupling layer in accordance with some embodiments of the invention;

FIG. 8 is a schematic side view of a package having a double layer of soft material stress decoupling layers in combination with a CTE matched interposer in accordance with some embodiments of the invention;

FIG. 9 is a schematic perspective view of a die-interposer subassembly in accordance with some embodiments of the invention;

FIG. 10 is a schematic cross-sectional view of a die-interposer alignment tool in accordance with some embodiments of the invention;

FIG. 11A is a schematic perspective view of the front side of a package substrate in accordance with some embodiments of the invention;

FIG. 11B is a schematic perspective view of the back side of the FIG. 11A substrate;

FIG. 12 is a schematic perspective view of a package with headers in accordance with some embodiments of the invention;

FIG. 13 is a schematic perspective view of a package with a pin grid array in accordance with some embodiments of the invention; and

FIG. 14 is a schematic cross-sectional view of an electromagnetic device package with a magnetic support plate in accordance with further embodiments of the invention.

### DETAILED DESCRIPTION OF PREFERRED EMBODIMENTS

The present invention is generally directed to the packaging of microsystem devices and to reducing warpage in such devices. Some embodiments of the invention are generally directed to incorporating magnets into the packaging of electromagnetic microsystem devices, which may be sealed hermetically.

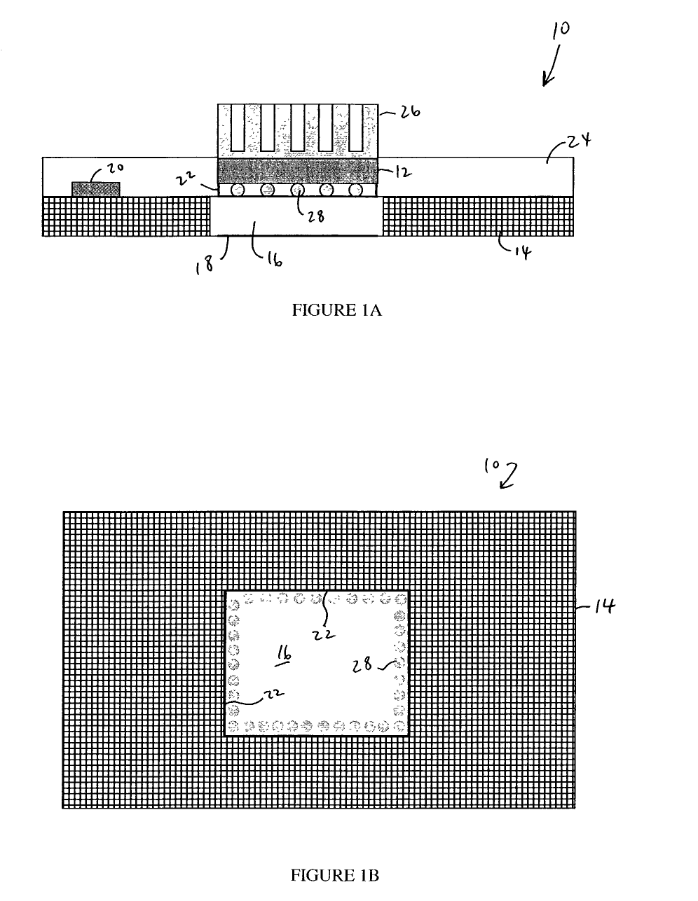

One or more embodiments of the invention are directed to packaging a microsystem device by flip chip attaching the device to a CTE matched substrate. FIGS. 1A and 1B schematically illustrate an example of a package 10 having a microsystem device 12 (which in this example is an optical MEMS device) directly flip chip attached onto a CTE matched substrate 14 that can provide the signal access.

Various materials can be used for the substrate including, e.g., ceramic, polymer, semiconductor, metal, and metal alloy materials. Particular examples of materials can include silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

Various materials can be used for the device die including, e.g., borosilicate glass and semiconductor materials. Particular examples of materials include gallium arsenside, silicon germanium, indium phosphide, and indium gallium arsenide phosphide.

The substrate 14 comprises a material having a CTE substantially matching that of the device die. The range within which the CTE of the die and substrate should match depends on the size of the die. For many applications, the substrate CTE preferably matches the die CTE to within a range of about 5×10⁻⁶/° C. The following tables list non-limiting examples of various possible die and substrate materials (and their respective CTE values) that can be suitably matched. (In both tables, the CTE values are for a temperature range between 20° C.-300° C.)

| Suitable Die | |
|---|---|
| Materials | CTE (×10⁻⁶/° C.) |
| Silicon | ˜3.2 |
| Galium | ˜5.4 |
| Arsenide | |
| Silicon nitride | ˜2.8 |

| Suitable | |
|---|---|
| Compatible Materials | |
| for Substrate | CTE (× 10^{-6/° C.)} |
| Alumina | ˜5.5-6.7 |
| Low Temperature Co- | ˜5.7 |
| fired Ceramic (LTCC) | |
| Berillia | ˜6.4 |
| Borosilicate Glass | ˜3.25-4 |
| Aluminum Nitride | ˜4.5 |
| ASTM F15 Alloy | ˜5.8 |
| NiFe alloys | ˜1.8-8 |

The package substrate 14 can be configured to provide signal access therethrough, e.g., for electrical, mechanical, chemical, thermal, magnetic, or optical signals depending on the function of the device. For example, if the device is an optical device, the substrate 14 can include a window 16 to permit the transmission of optical signals therethrough to the device 12. The window 16 can, for instance, allow light of a specified wavelength to be transferred through the substrate. The substrate can be transparent and selectively covered in the window transmission area with anti-reflective (AR) and/or filter coatings 18.

For other types of devices, signals relating to other measures, e.g., pressure, gas, and flow, can be transferred to the device through the substrate 14 by using, e.g., membranes, openings with filters, and channels, respectively.

The rest of the substrate 14 can be used to carry thick or thin film circuitry for lead transfer from the device. High density lead transfer can be achieved. Portions of the substrate can also be used to support other active or passive electronic components 20.

One advantage of the package 10 is that the design is simplified by combining the signal access mechanism (e.g., the optical window) and the substrate into a single structure. This reduces the number of parts and number of bond layers needed. Reducing the number of bond layers will improve yield for the hermetic package (less area for leakage, reduces risk of having volatiles trapped in the package, etc.). In addition, the cost of package fabrication is reduced. Also, because the signal transfer mechanism is integrated in the substrate, the size of the package can be reduced.

Flip chip structures can be added around the periphery of the device area to electrically interconnect and mechanically hold the device around the signal access area 16. A seal ring 22 can provide a hermetic seal selectively around the active device area to protect device components from the environment.

The area outside the sealed active component area can be encapsulated. Relatively inexpensive plastic encapsulation 24 can be used because the hermetic seal is preferably used to cover only the most sensitive components of the device 12. The plastic encapsulation can also assist in forming a more rigid structure and to protect interconnects and other electrical components.

The side of the device 12 opposite the substrate is accessible and can be equipped with thermal management solutions 26 such as, e.g., heat spreaders, fins, fans and cooling fluid mechanisms. Having the backside of the die accessible for the temperature control mechanisms simplifies system design. Alternatively, the side of the device 12 opposite the substrate can be used to house the magnets for electromagnetic devices.

The package 10 can allow multichip modules to be achieved by integration of additional active and passive circuitry 20 on the same package substrate 14. This can allow for a further reduction of the system size and cost and at the same time increase systems performance.

The package 10 allows for lower systems cost due to a reduced number of components, use of simple thick or thin film technology, high degree of automated assembly, and high degree of integration.

By way of example, the process for packaging a microsystem can be as follows, but not necessarily in order:

1. Use a thick or thin film process to apply circuitry pattern to the CTE matched substrate 14, avoiding the signal access area 16. In this process, solderable bond pads can be applied around the perimeter of the die area for flip chip contacts. Metallization can also be added around the area of sensitive components to be used as a sealing frame.

2. Apply flip chip bumps 28 (using, e.g., gold stud bumping, stenciling or dispensing conductive polymer bumps, stenciling or dispensing solder paste bumps, soldering spheres using flux to hold spheres in place and a stencil to identify placement, thin film deposition, or electroless- or electro-plating) to the die perimeter or the substrate pads for electrical interconnection. The same or a different technology can be used to deposit a sealing frame 22 surrounding the sensitive component area of the device 12. The sealing frame can be deposited onto the die or the substrate.

3. For optical devices, selectively apply an optical coating 18 to the area of window 16 that will mate with the optical structures in the device. The coating can be applied before or after thick or thin film processes. The optical coating 18 can be applied through a shadow mask to define the area, or it can be selectively removed after the coating process. As shown in FIG. 1A, the coating 18 is applied to the side of the substrate 14 opposite the device 12. Alternatively, it may be applied to the same side of the substrate as the device or, alternatively, on both sides of the substrate.

4. Place the device (e.g., using a flip chip placer), aligning the flip chip bumps 28 with the solderable bond pads on the mate.

5. Establish the flip chip connections by, e.g., reflowing solder, curing or remelting polymers, or diffusion of metals. At this time, the sensitive components will be sealed hermetically, if the frame surrounding the components has been applied.

6. Additional electronic components 20 can be added and connected with the thick or thin film circuitry.

7. For further protection, the module can be encapsulated using a polymeric component 24, e.g., epoxy, silicone, or polyurethane. The encapsulation can be done by, e.g., molding, potting, or dispensing.

8. Additional components 26 can be added to the device 12 for thermal management or control such as, e.g., heat sinks, fans, liquid cooler, phase change coolers, thermo-electrical cooler, or magnets for electromagnetic devices. For closer proximity of such components to the device, the thickness of the encapsulation covering such components can be reduced, or parts of the component can possibly be exposed. Closer proximity yields better heat transfer in the case of thermal management, or stronger magnetic field in the case of magnet assemblies.

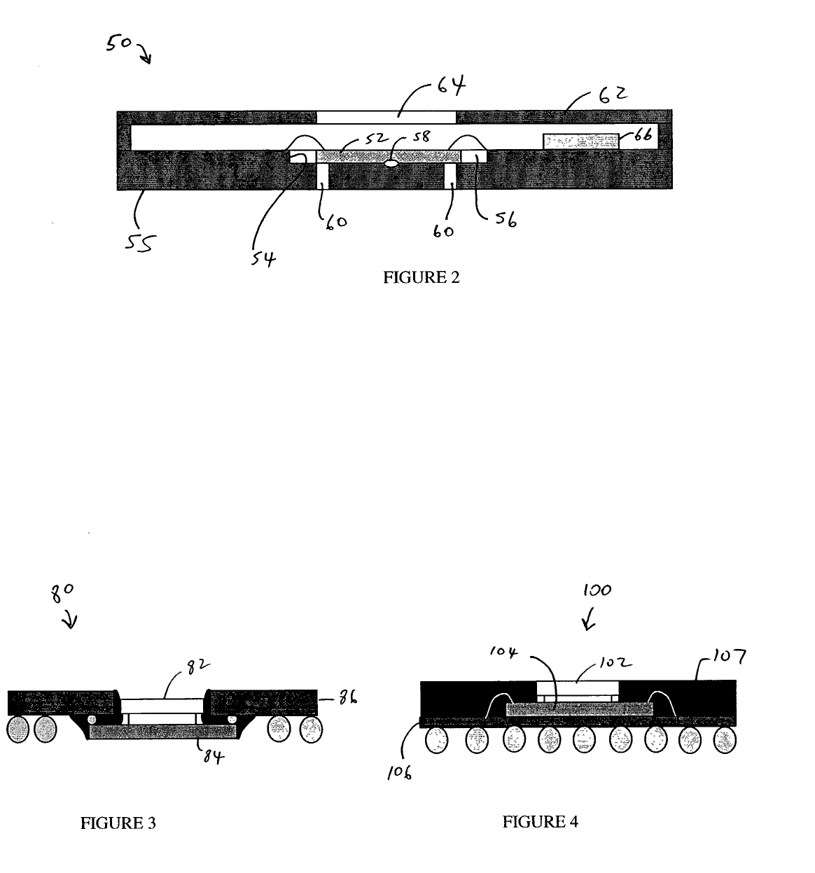

FIG. 2 illustrates a package 50 in accordance with further embodiments of the invention. A microsystem device 52 is placed in a recess 54 in a low CTE package substrate 55 (e.g., ASTM F15 Alloy, Ni alloys, Fe alloys, Co alloys, Si, LTCC, AlN, beryllia, glass, liquid crystal polymer, carbon composite, soft magnetic material, or alumina). The device die is bonded (using a conductive or non-conductive adhesive or solder 56) on its sides, to the sidewalls of the substrate 55 defining the recess 54. The CTE of the bonding material 56 and the width of the bond gap (i.e., the space between the sides of the die and the recess sidewalls) can be chosen such that it offsets the CTE mismatch between the substrate and the die. Thus, the die 52 remains generally flat and potentially under slight tension over a wide temperature range.

A small dot of stiff adhesive or solder 58 in the center of the die can be used to hold the die 52 in place during assembly. Also, vacuum holes 60 can be provided in the substrate 55 underneath the die 52. The holes 60 penetrate through the bottom of the package, and can hold the device 52 down with an applied vacuum while wire bonding, thus enabling efficient coupling of the ultrasonic bonding power. The vacuum holes 60 can be hermetically sealed after the assembly process by various methods including, but not limited to, welding, brazing, and soldering. A lid 62 with an integrated signal transfer window 64 (e.g., an AR coated transparent window for optical devices, or a membrane for pressure sensors) can be used to hermetically seal the package. Such a package can also be used to integrate additional electronic circuitry 66 in close proximity to the device such as, e.g., local control, signal conditioning, or feedback function.

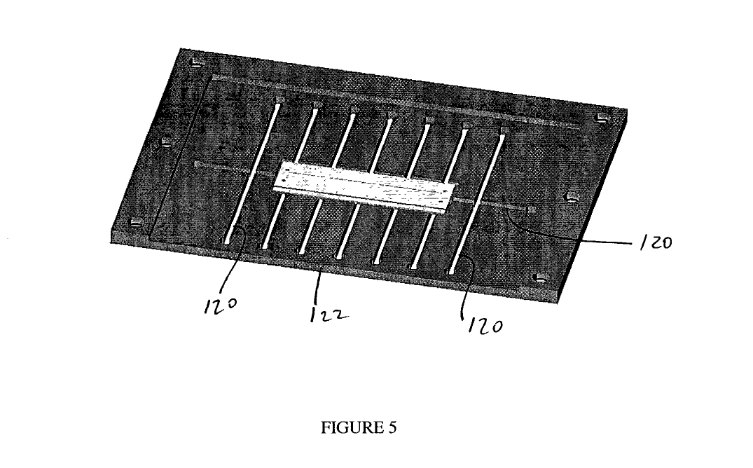

Device packages 80, 100 in accordance with some further embodiments of the invention are shown in FIGS. 3 and 4, respectively. In these packages, a signal transfer window 82, 102 is hermetically sealed to a device 84, 104 mounted on a package substrate to protect sensitive components.

Electrical interconnection to the device die can be achieved by using, e.g., flip chip bonding (as shown in FIG. 3), wire bonding (as shown in FIG. 4), or tape automated bonding (TAB).

The substrate 86, 106 is preferably a low stress material such as, e.g., CTE matching ceramic or flexible tape.

An inexpensive plastic encapsulation 107 (e.g., glob top, transfer molding, potting, or underfill) can be provided to protect interconnects and other electrical components of the package. The plastic encapsulation 107 can also assist in providing a more rigid package structure.

The window 82, 102 is cut to selectively cover the active area of device 84, 104. The window can comprise a CTE matched material such as, e.g., AR coated Pyrex 7740. The hermetic seal may be achieved by, e.g., glass frit, eutectic, solder, anodic bonding, isothermal solidification, diffusion bonding, thermo-compression bonding.

In the FIG. 4 package 100, the device die 104 has a CTE substantially matching that of the substrate 106.

One advantage of the FIGS. 3 and 4 package design is that the hermetic seal is isolated to the area of the sensitive components, allowing less expensive, less complicated encapsulation of the remaining circuitry. No additional hermetic sealing is required.

In addition, the selective hermetic seal of the sensitive area is on the wafer level, thus, significantly reducing cost by using highly parallel wafer level processing.

The package 80 of FIG. 3 enables simple thermal management, because the backside of the chip 84 is accessible for temperature control mechanisms such as, e.g., by fins, fans, cooling fluid, heat spreader. Alternatively, the backside of the chip 84 is accessible for magnets for electro-magnetic devices.

Device die warpage can be further reduced using various approaches such as, e.g., mechanically decoupling the device from the substrate and reducing stress from displacement in the substrate. These approaches can be used separately or in some combination.

In accordance with some embodiments of the invention, stress in a package substrate can be reduced by, e.g., forming stress-reducing slots 120 in the substrate 122 (as shown in FIG. 5) to make it more compliant and to reduce cumulative displacement caused by a CTE mismatch. Furthermore, the substrate 122 can comprise a low stress material such as, e.g., a CTE matching metal, glass, or ceramic or flexible tape, or a low modulus polymeric material.

Stress-reducing slots can similarly be formed in interposer structures, which are described below.

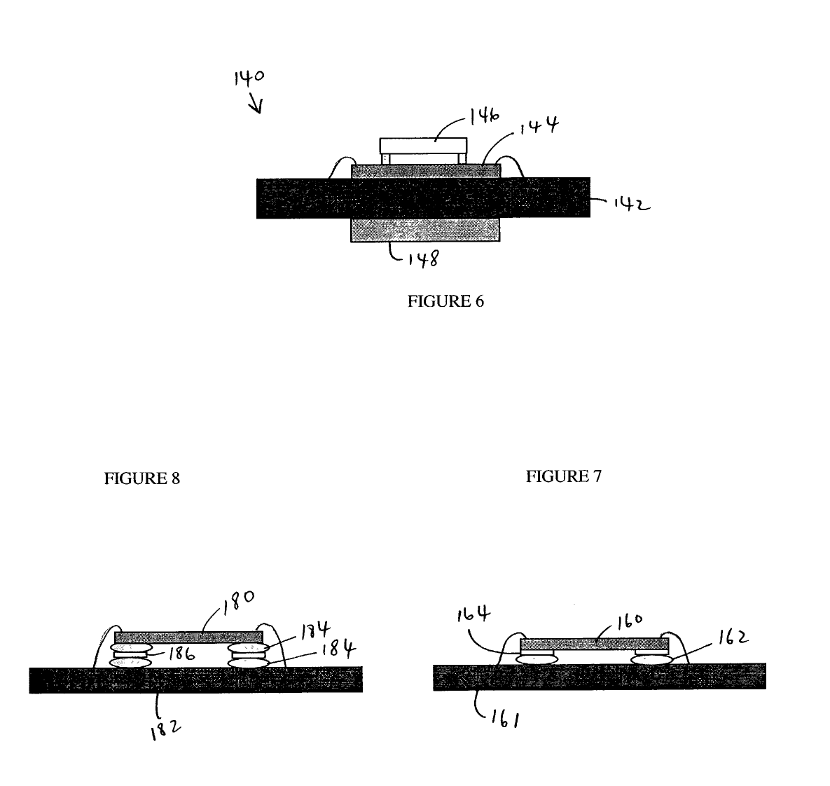

In accordance with some further embodiments of the invention, the package can be designed to have mechanical and thermo-mechanical symmetry across the package substrate, in order to balance CTE mismatches. By way of example, FIG. 6 illustrates a package 140 having a substrate 142 with a device 144 mounted thereon, which in this example has a wire bond interconnect. A signal transfer window 146 is mounted on the device 144. A complimentary structure 148 for symmetry of CTE, structure, and stiffness is mounted on the opposite side of the substrate 142. Creating a comparable and opposite stress acting on both sides of the device assists in keeping the device flat.

In accordance with further embodiments of the invention, devices are decoupled from stress in the substrate due to displacement from CTE mismatches using intermediate structures or interposers, which form stress decoupling layers between the package substrate and the device.

In accordance with some embodiments of the invention, layers of a soft material are positioned between the package substrate and the device. The device can be directly or indirectly mounted on the soft material. The soft material is configured to absorb stress caused by CTE mismatches between the substrate and the device.

By way of example, FIG. 7 illustrates a device 160 mounted on a substrate 161. The device 160 is indirectly mounted on a soft material layer 162 with an intermediate, CTE matched mounting plate 164 between the die 160 and the soft layer of material 162. The mounting plate (e.g., glass or ceramic materials) may be used to stiffen the device, so that it will be wire-bondable, and less prone to warpage.

As another example, FIG. 8 illustrates a device 180 mounted on a substrate 182 with a double layer of a soft material structure therebetween. The structure includes two layers of soft material 184 separated by a mounting plate 186.

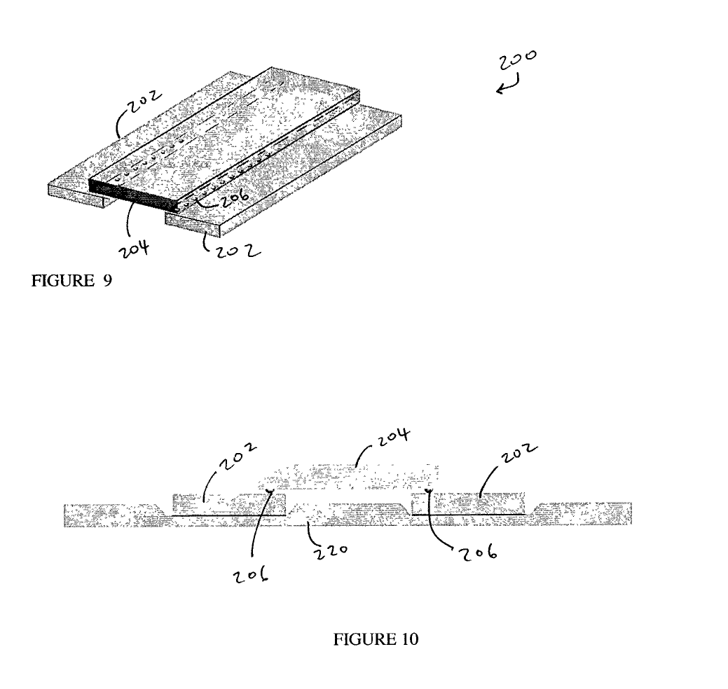

In accordance with some embodiments of the invention, the interposers can be two spaced-apart members 202 or mounting plates as shown, e.g., in FIG. 9, which illustrates a die-interposer subassembly 200 that can be inserted into a package as will be described below. The interposers 202 are preferably generally stiff strips of a material having a CTE substantially matching that of the die 204, e.g., Pyrex 7740, silicon, borosilicate glass, liquid crystal polymers, carbon composites, alumina, beryllia, LTCC, aluminum nitride or ASTM F15 Alloy. Alternatively, a single, picture-frame style of interposer material may be used. The picture frame will further help to stiffen and support the device.

The mounting plates 202 are preferably mounted along opposite sides of the die 204 and are aligned along the axis where a low die curvature is desired. The plates 202 are arranged in such a way that there is generally no interference with the active components of the device 204. The interposers 202 decouple the device 204 from thermo-mechanical stresses from the substrate material. Also, the interposers 202 can further stiffen the device.

The die-interposer subassembly 200 is particularly suitable for use in the packaging of electromagnetic devices operated with magnets as will be described below. Such devices can include, e.g., electro-magnetically actuated MEMS devices.

In the die-interposer subassembly 200, the device 204 is preferably attached to the interposer members 202 such that the interconnects 206 from the device are positioned on a side of the device 204 facing the magnet that will be inserted in the package. Having the interconnects 206 on the magnet side of the device allows single sided circuitry on the device and accordingly reduces the number of mask sets needed in the lithography process. The device is flip chip bonded onto the flat, CTE matching interposer plates 202, which fan-out the lead pattern to wirebond pads.

When assembled, the interposer plates 202 preferably straddle the magnet or magnets to thereby position them under the die, enabling passive alignment of the magnets with respect to the die.

In addition, flip chip interconnection techniques used between the die and interposer plates 202 enable a higher interconnection density than wire bonding, resulting in a smaller die size. A smaller sized die is advantageous because it is more rigid than a larger die of the same thickness. Having a smaller die size also reduces the effect of CTE mismatch between package components and die. In addition, smaller dies increase the number of devices that can be processed per wafer, thereby reducing the overall cost of the device.

The interposers 202 can be attached to the package substrate with a low stress die attach, to mechanically de-couple the die from the substrate (as, e.g., in FIG. 7).

Using flip chip bonding for attaching the device to the interposer allows a choice between using soft solder (which is particularly suited for precise self-alignment), or a polymer for low temperature and stress.

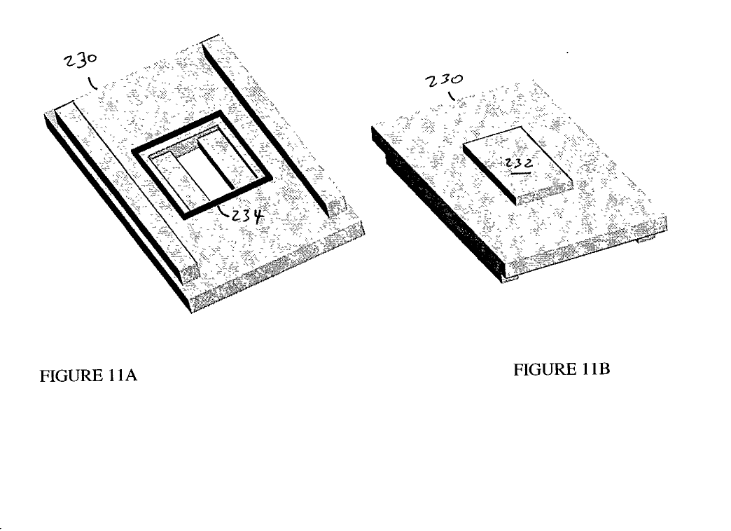

A die-interposer alignment tool 220 such as a precision jig (illustrated, e.g., in FIG. 10) can be used to accurately align the two interposer plates 202 with respect to each other, in preparation for flip chip bonding with the die. Having tight control of the distance between the interposers 202 will enable passive alignment of the device to the package, particularly with respect to magnets in the package. This obviates the need for alignment mechanisms such as, e.g., mechanisms using set screws. Precision jigs can be made from, e.g., micro machined Si.

FIGS. 11A and 11B show front and back views, respectively, of a package substrate 230, in which the die-interposer subassembly 200 can be mounted. The substrate includes a cutout, beneath which a magnetic baseplate 232 is brazed thereon as shown in FIG. 11B. The brazing step is preferably performed before magnets are assembled in the package because the brazing temperature might degrade the magnets. A seal ring 234 (shown in FIG. 11A) can also be brazed to the front of the package.

After the brazing process, magnets are carefully inserted into the substrate cutout and positioned on top of the magnetic baseplate, where magnetic forces hold them in place. The magnets are arranged relative to one another before they are inserted into the cutout area. The die-interposer subassembly 200 can then be aligned over the magnets, and bonded to the ceramic substrate 230. A compliant die attach can be used to relieve stress. If the mechanical tolerances of the magnets and the subassembly 200 are kept sufficiently close, passive alignment can be achieved between the subassembly and the magnets.

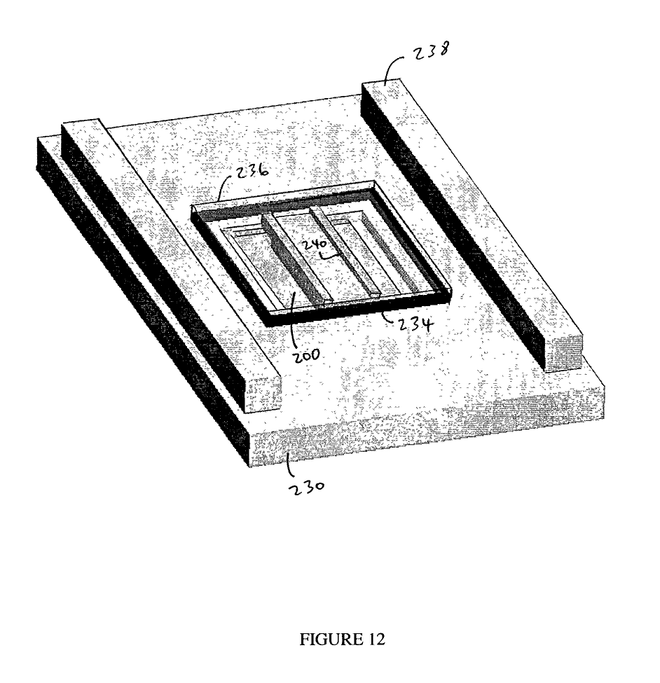

The interposers 202 are then wirebonded to the ceramic substrate 230, to provide interconnection to the device 204. After interconnection is complete, the signal transmission window 236 is seam sealed or laser welded to the seal ring 234 as shown in FIG. 12. This allows hermetic sealing with generally only localized heating, so that the temperature sensitive components, e.g., magnets, microsystems or other device components, and flip chip joints are not exposed to a high sealing temperature.

The FIG. 12 package utilizes high-density headers 238 on the substrate, which can be soldered on the substrate 230. To avoid high temperature exposure of the magnets, this can be performed before the magnets have been inserted. This approach is advantageous because it allows for low cost, quick prototyping, using standard hybrid thick film technology and commercially available headers and cables. Alternatively, localized heating (e.g., hot gas, hot bar soldering, or soldering iron) can be used to avoid over-heating the magnets.

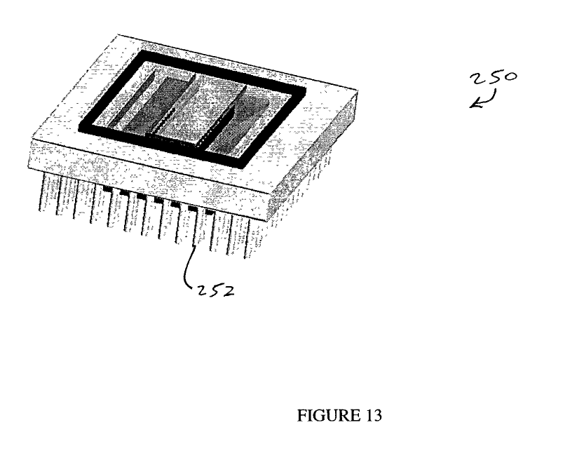

FIG. 13 illustrates a similar package 250 having a pin grid array (PGA) 252 instead of the headers 238, which allows the package to be made smaller. (The shrinkage factor is dependent on, e.g., available header size/shape/density, the density limitations of the PGA technology, die size, and magnet size). The FIG. 13 package 250 can, e.g., be plugged into a socket mounted to a motherboard, for system integration. Other alternative package outlines include ball grid array, stud grid array, column grid array, and land grid array.

Additional measures can be taken, if desired, to further reduce die warpage. For instance, die warpage can be further reduced by attaching flat, CTE matched, stiffener beams 240 to the side of the device 204 facing away from the magnets as shown, e.g., in FIG. 12.

Alternatively, a clamping frame or stiffener ring can be mounted on the device, preferably around the side of the device facing away from the magnets. The clamping frame can optionally apply active pressure to the device for warpage control.

Alternatively, piezoelectric strips can be attached to the device, to actively flatten the device. The piezoelectric strips can apply a controllable force to off-set thermo-mechanically induced stress to prevent device warpage.

Advantages of using the additional measures for reducing die warpage include providing mechanical/CTE symmetry across the device, creating a comparable and opposite stress acting on both sides of the device, thus keeping it flat. The additional measures will generally not interfere with the electrical interconnection of the device to the substrate.

There are several advantages to using the interposer-die subassembly. The interposer preferably has a CTE close to that of the die, which can, e.g., be silicon, SiGe, borosilicate glass, liquid crystal polymers, carbon composites, alumina, beryllia, LTCC, aluminum nitride and ASTM F15 Alloy. The interposer mechanically isolates the die to reduce thermo-mechanical stress and mechanically supports the die. The interposers are preferably compatible with thin film processing to allow lead transfer from the device. The interposers can be transparent, which allows flip chip inspection and facilitates alignment of the subassembly over the magnets.

User of separate interposers is compatible with dicing, as there would be straight cuts and no cut-outs required. Use of separate spacers also allows the assembly to straddle magnets to minimize spacing between the magnets and the die. Use of a single, picture-frame style interposer would help to stiffen and support the device even further.

There are several advantages to using a solder reflow flip chip process to attach the die to the interposers. For instance, the flip chip reflow solder process self aligns (through surface tension) the device with the substrate. In addition, the solder reflow process is generally stress free. Also, for magnetically actuated MEMS devices using actuation coils, flip chip technology allows the bonding pads to be on coil side of MEMS device. Furthermore, solder spheres used in flip chip bonding absorb stress, and can be used to set a given stand-off height above the magnets. Various materials can be used for solder spheres including, e.g., SnPb, SnPbAg, InSn, SnAgCu, SnAgBi, or PbIn alloys (such as a 37Sn63Pb or 50Pb50In alloy).

In accordance with some embodiments of the invention, silicone material filled with glass spacers can be used to join the die-interposer assembly to the package substrate. The glass spacers maintain the device at a repeatable, consistent gap or stand-off from the magnets. The rheology of the material is suitable for automatic dispensing and reduces the time needed for the assembly. Suitable glass spacer filled silicone material can include, e.g., Dow Corning 7030 Die Attach Adhesive available from Dow Corning. This is a spacer-filled, heat-cure DRAM grade silicone die attach that allows the control of bond line thickness and does not require a primer. The spacers are available in 75 micron and 50 micron diameter spheres. The glass spacer filled silicone material has a primeness die attach formulation, which speeds the assembly process. Also, the material has low ionics, superior moisture resistance, and low volatility, making it particularly suitable for use with hermetic packaging.

The silicone provides stress relief, and reduces thermo-mechanical stresses and die bow. It has a low modulus (28 MPa), allowing stress to be absorbed in the adhesive layer rather than transferring it to the device.

The glass spacer filled silicone material also advantageously has a low cure temperature of about 150 degrees Celsius.

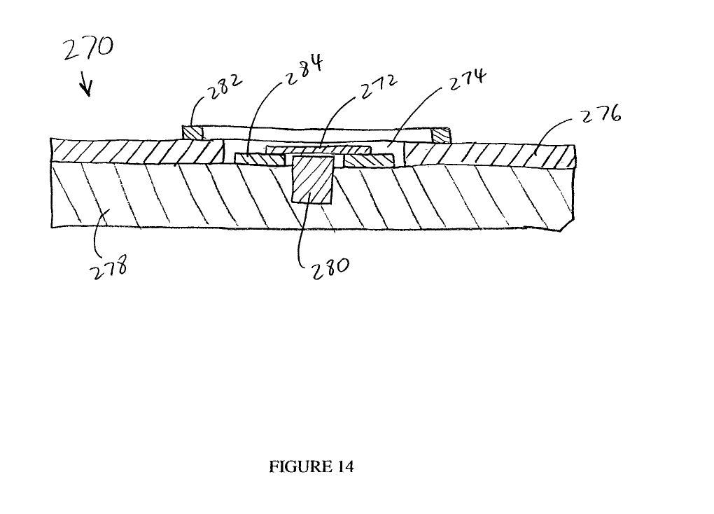

FIG. 14 is a schematic cross-sectional view of a package 270 with a magnetically actuated device 272 in accordance with some further embodiments of the invention. The package includes a die-interposer subassembly mounted in an opening 274 in a substrate 276. The substrate is mounted on a ferro-magnetic support plate 278. A magnet 280 is also positioned on the support plate 278 beneath the die 272. A seal ring 282 on the substrate surrounds the device on the substrate for hermetically sealing the device.

The support plate material is preferably ferro-magnetic (e.g., ASTM F15 alloy or other Ni, Fe, or Co alloys), allowing a single component to serve as a magnet baseplate and a support structure for the ceramic substrate and die-interposer subassembly.

Generally tight tolerances are used in the various components of the package to facilitate passive alignment of components during package assembly. For instance, tight tolerances (within 0.001 inches) can be achieved for the magnet cavity in the support plate 278. Also, similarly tight tolerances used for the surface of the package supporting the die-interposer subassembly. The magnet height preferably has a +/−½ mil tolerance in order to minimize variation of the gap between magnets and device.

Passive alignment reduces the assembly time needed for assembling the magnet in the package. For instance, the time required for the magnet assembly process can be reduced from about 40 minutes for active alignment to about <5 minutes for passive alignment.

Having described various preferred embodiments of the present invention, it should be apparent that modifications can be made without departing from the spirit and scope of the invention.

1. A microsystem package, comprising:
a microsystem device including a device die; and
a substrate to which said microsystem device is flip chip bonded, said substrate having a CTE substantially matching that of the device die, said substrate including an opening for transmission of signals therethrough to said device.

2. The package of claim 1 further comprising a window at said opening.

3. The package of claim 2 wherein at least a portion of said microsystem device proximate said window is hermetically sealed to said substrate.

4. The package of claim 2 wherein said substrate is substantially transparent.

5. The package of claim 2 wherein said signals comprise optical signals and said window is coated with an anti-reflective material.

6. The package of claim 2 wherein said signals comprise optical signals and said window is coated with an optical wavelength filter.

7. The package of claim 2 further comprising circuitry on said substrate outside of said window.

8. The package of claim 7.wherein said circuitry includes additional active or passive electronic components or both.

9. The package of claim 3 wherein at least a portion of said substrate outside of said hermetically sealed portion of said microsystem device is encapsulated.

10. The package of claim 1 further comprising a thermal management component on a side of said microsystem device opposite said substrate.

11. The package of claim 1 further comprising a magnet assembly on a side of said microsystem device opposite said substrate.

12. The package of claim 1 wherein said substrate comprises a material selected from the group consisting of ceramic, polymer, semiconductor, metal, and metal alloy materials, and wherein said die comprises a material selected from the group consisting of borosilicate glass and semiconductor materials.

13. The package of claim 1 wherein said microsystem device comprises a MOEMS device, a MEMS device, an electro-optical device, an electromechanical device, an electromagnetic device, an electrothermal devices, a piezoelectric devices, or an electrostatic device.

14. A microsystem package, comprising:
a microsystem device; and
a substrate including a recess for receiving said microsystem device; and
a material between sides of said microsystem device and sidewalls defining said recess in said substrate for reducing thermo-mechanical stresses applied to said microsystem device.

15. The package of claim 14 wherein said microsystem device is wire bonded to said substrate.

16. The device of claim 14 further comprising a lid hermetically sealed to said substrate, said lid including a window for transmission of signals therethrough to said device.

17. The package of claim 16 wherein said signals comprise optical signals and said window is coated with an anti-reflective material.

18. The package of claim 16 wherein said signals comprise optical signals and said window is coated with an optical filter.

19. The package of claim 14 further comprising circuitry on said substrate on portions of said substrate outside said device.

20. The package of claim 19 wherein said circuitry includes additional electronic components.

21. The package of claim 14 further comprising at least one hole extending through said substrate beneath said recess, said at least one hole for holding said device in place under vacuum in said recess during assembly.

22. The package of claim 21 wherein said at least one hole is hermetically sealed after said assembly.

23. The package of claim 14 further comprising an adhesive beneath said device for holding said device in place in said recess during assembly.

24. The package of claim 14 wherein said substrate comprises a material selected from the group consisting of ceramic, polymer, semiconductor, metal, and metal alloy materials, and wherein said microsystem device includes a die comprising a material selected from the group consisting of borosilicate glass and semiconductor materials.

25. The package of claim 14 wherein said microsystem device comprises a MOEMS device, a MEMS device, an electro-optical device, an electromechanical device, an electromagnetic device, an electrothermal device, a piezoelectric device, or an electrostatic device.

26. An microsystem device package, comprising:
a substrate having an opening extending therethrough;
a microsystem device flip chip bonded to one side of said substrate around said opening; and
a signal transfer window having a CTE substantially matching that of the device, said signal transfer window positioned at said opening and allowing signals to be transmitted therethrough to said device, said signal transfer window hermetically sealing at least a portion of said microsystem device.

27. The package of claim 26 wherein said signals comprise optical signals and said window is coated with an anti-reflective material.

28. The package of claim 26 wherein said signals comprise optical signals and said window is coated with an optical filter.

29. The package of claim 26 further comprising additional circuitry on said substrate.

30. The package of claim 26 further comprising a thermal management component on a side of said device opposite said substrate.

31. The package of claim 26 further comprising a magnet assembly component on a side of said electromagnetic device opposite said substrate.

32. The package of claim 26 wherein said substrate comprises a material selected from the group consisting of ceramic, polymer, semiconductor, metal, and metal alloy materials, and wherein said microsystem device includes a die comprising a material selected from the group consisting of borosilicate glass and semiconductor materials.

33. The package of claim 26 wherein said microsystem device comprises a MOEMS device, a MEMS device, an electro-optical device, an electromechanical device, an electromagnetic device, an electrothermal device, a piezoelectric device, or an electrostatic device.

34. An microsystem device package, comprising:
a substrate;
a microsystem device wire bonded to said substrate, said microsystem device including a die with a CTE substantially matching that of the substrate; and
a signal transmission window for allowing transmission of signals therethrough to said device, said signal transmission window mounted on and hermitically sealing at least a portion of said device.

35. The package of claim 34 wherein said signals comprise optical signals and said window is coated with an anti-reflective material.

36. The package of claim 34 wherein said signals comprise optical signals and said window is coated with an optical wavelength filter.

37. The package of claim 34 wherein at least a portion of said substrate outside of said hermetically sealed portion of said microsystem device is encapsulated.

38. The package of claim 34 wherein said substrate comprises a low stress material.

39. The package of claim 34 wherein said substrate comprises a material selected from the group consisting of ceramic, polymer, semiconductor, metal, and metal alloy materials, and wherein said microsystem die comprises a material selected from the group consisting of borosilicate glass and semiconductor materials.

40. The package of claim 34 wherein said microsystem device comprises a MOEMS device, a MEMS device, an electro-optical device, an electromechanical device, an electromagnetic device, or an electrostatic device.

41. A microsystem device package, comprising:
a microsystem device; and
a substrate on which said microsystem device is mounted, said substrate including at least one slot therein for increasing compliance of said substrate and reducing thermo-mechanical stresses applied to said device.

42. The package of claim 41 wherein said device includes a device die, and wherein said substrate has a CTE substantially matching that of the device die.

43. The package of claim 41 wherein said substrate comprises a low stress material.

44. The package of claim 41 wherein said substrate comprises a material selected from the group consisting of ceramic, polymer, semiconductor, metal, and metal alloy materials, and wherein said device includes a die comprising a material selected from the group consisting of borosilicate glass and semiconductor materials.

45. The package of claim 41 wherein said microsystem device comprises a MOEMS device, a MEMS device, an electro-optical device, an electromechanical device, an electromagnetic device, an electrothermal device, a piezoelectric device, or an electrostatic device.

46. A microsystem device package, comprising:
a microsystem device including a device die;
a substrate on which said microsystem device is mounted; and
an interposer structure between said device die and said substrate for substantially decoupling the die from thermo-mechanical stresses resulting from relative movement of said substrate.

47. The package of claim 46 wherein said interposer structure comprises a compliant material.

48. The package of claim 47 wherein said compliant material comprises a soft gasket layer.

49. The package of claim 47 further comprising a mounting plate between said compliant material layer and said die.

50. The package of claim 46 wherein said interposer structure comprises two compliant material layers separated by a mounting plate therebetween.

51. The package of claim 46 wherein said interposer structure comprises two spaced-apart plates.

52. The package of claim 46 wherein said interposer structure comprises two plates that are affixed along two opposite sides of said die.

53. The package of claim 52 wherein said plates have a CTE substantially matching that of said die.

54. The package of claim 46 wherein said interposer structure has a CTE substantially matching that of said die.

55. The package of claim 46 wherein said die is flip chip bonded to said interposer structure.

56. The package of claim 46 wherein said interposer structure is wire bonded to said substrate.

57. The package of claim 46 wherein said interposer structure comprises a material selected from the group consisting of borosilicate glass, silicon, liquid crystal polymers, carbon composites, alumina, beryllia, LTCC, aluminum nitride and ASTM F15 Alloy.

58. The package of claim 46 wherein said interposer structure comprises plates positioned on opposite sides of one or more magnets mounted in said package.

59. The package of claim 46 further comprising a window on said substrate hermetically sealing at least a portion of said die.

60. The package of claim 46 further comprising at least one stiffening element on said device.

61. The package of claim 60 wherein said at least one stiffening element comprises at least one stiffening beam having a CTE substantially matching that of the device die.

62. The package of claim 46 further comprising a support plate on which said substrate is mounted.

63. The package of claim 46 wherein said microsystem device comprises a MOEMS device, a MEMS device, an electrothermal device, a piezoelectric device, a thermomechanical device, an electro-optical device, an electromechanical device, an electromagnetic device, or an electrostatic device.

64. An electromagnetic device assembly, comprising:
a package substrate;
at least one magnet mounted on said package substrate;
an electromagnetic device including a device die; and
at least one interposer plate, on which said electromagnetic device is flip chip bonded, said at least one interposer plate being connected to said substrate.

65. The assembly of claim 64 where said at least one interposer plate has a CTE substantially matching that of said device die.

66. The assembly of claim 64 wherein said at least one interposer plate is wirebonded to said substrate.

67. The assembly of claim 64 where said at least one interposer plate comprises two interposer plates positioned in said package to generally straddle said at least one magnet.

68. The assembly of claim 64 further comprising a signal transmission window covering at least one portion of said electromagnetic device.

69. The assembly of claim 64 further comprising a signal transmission window covering and hermetically sealing at least a portion of said electromagnetic device.

70. The assembly of claim 69 wherein at least a portion of said substrate outside of said hermetically sealed portion of said electromagnetic device is encapsulated.

71. The assembly of claim 64 wherein said at least one interposer plate comprises a material selected from the group consisting of borosilicate glass, silicon, liquid crystal polymers, carbon composites, alumina, beryllia, LTCC, aluminum nitride and ASTM F15 Alloy and wherein said die comprises a material selected from the group consisting of borosilicate glass and semiconductor materials.

72. The assembly of claim 64 wherein said substrate comprises a material selected from the group consisting of ceramic, polymer, semiconductor, metal and metal alloy materials.

73. The assembly of claim 64 further comprising a support plate for supporting said substrate.

74. The assembly of claim 64 wherein said at least one interposer plate is bonded to said substrate using a compliant material.

75. The assembly of claim 74 wherein said compliant material comprises a spacer filled silicone material.

76. A method of manufacturing an electromagnetic device package, comprising:
making a die-interposer subassembly by positioning two interposer plates along opposite sides of an electromagnetic device and flip chip bonding the device to the plates;
assembling at least one magnet with a package substrate;
assembling the die-interposer subassembly with the substrate such that the two interposer plates generally straddle said at least one magnet; and
wire bonding the interposer plates to the substrate.

77. The method of claim 76 further comprising sealing a signal transmission window over at least a portion of said electromagnetic device.

78. The method of claim 76 wherein the two interposer plates are positioned along the opposite sides of said electromagnetic device using a jig.

79. The method of claim 76 wherein assembling the die-interposer subassembly with the substrate includes passively aligning said subassembly with a given portion of the substrate.

80. The method of claim 79 wherein said given portion comprises a recess for receiving said plates.

81. The method of claim 76 wherein assembling the die-interposer subassembly with the substrate includes attaching the interposer plates to the substrate using a compliant material.

82. The method of claim 81 wherein said compliant material comprises a spacer filled silicone material.

83. The method of claim 76 wherein assembling at least one magnet with a package substrate includes passively aligning the at least one magnet to a given portion of the substrate.

84. The method of claim 83 wherein said given portion comprises a cavity for receiving said magnet.

85. The method of claim 76 further comprising encapsulating portions of said substrate outside of said at least one portion of said device.

86. The package of claim 12 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

87. The package of claim 12 wherein said die comprises a material selected from the group consisting of gallium arsenside, silicon germanium, indium phosphide, and indium gallium arsenide phosphide.

88. The package of claim 24 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

89. The package of claim 24 wherein said die comprises a material selected from the group consisting of gallium arsenside, silicon germanium, indium phosphide, and indium gallium arsenide phosphide.

90. The package of claim 32 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

91. The package of claim 32 wherein said die comprises a material selected from the group consisting of gallium arsenside, silicon germanium, indium phosphide, and indium gallium arsenide phosphide.

92. The package of claim 39 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

93. The package of claim 39 wherein said die comprises a material selected from the group consisting of gallium arsenside, silicon germanium, indium phosphide, and indium gallium arsenide phosphide.

94. The package of claim 44 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

95. The package of claim 44 wherein said die comprises a material selected from the group consisting of gallium arsenside, silicon germanium, indium phosphide, and indium gallium arsenide phosphide.

96. The assembly of claim 71 wherein said die comprises a material selected from the group consisting of gallium arsenside, silicon germanium, indium phosphide, and indium gallium arsenide phosphide.

97. The assembly of claim 72 wherein said substrate comprises a material selected from the group consisting of silicon, gallium arsenide, glass, borosilicate glass, liquid crystal polymers, carbon composites, alumina, beryllia, LTCC, aluminum nitride, soft magnetic material, Ni alloys, Fe alloys, Co alloys, and ASTM F15 alloy.

98. The package of claim 46 wherein said substrate includes at least one slot therein for increasing compliance of said substrate and reducing thermo-mechanical stresses applied to said device.

99. The package of claim 46 wherein said interposer structure includes at least one slot therein for increasing compliance of said structure and reducing thermo-mechanical stresses applied to said device.

100. The assembly of claim 64 wherein said substrate includes at least one slot therein for increasing compliance of said substrate and reducing thermo-mechanical stresses applied to said device.

101. The assembly of claim 64 wherein said at least one interposer plate includes at least one slot therein for increasing compliance of said plate and reducing thermo-mechanical stresses applied to said device.
